(19) United States
(12) Patent Application Publication
(10) Pub. No.: US 2024/0389246 A1
(43) Pub. Date: Nov. 21, 2024

(54) POWER SUPPLY WITH WATERPROOF COMPONENTS

(71) Applicant: TWS Technology (Guangzhou) Limited, Guangzhou (CN)

(72) Inventors: Charles Liu, Belmont, CA (US); Guang Ouyang, Guangzhou (CN); Qingyun Chen, Guangzhou (CN)

(21) Appl. No.: 18/317,301

(22) Filed: May 15, 2023

(51) Int. Cl. H05K 5/02; H01M 10/48; H01M 10/653; H01M 10/6551; H01M 10/6563; H01M 50/224; H01M 50/691; H05K 7/14; H05K 7/20

(52) U.S. Cl. CPC H05K 5/0217; H01M 10/48; H01M 10/653; H01M 10/6551; H01M 10/6563; H01M 50/224; H01M 50/691; H05K 7/14; H05K 7/20909

(57) ABSTRACT

Embodiments include a power supply that includes a non-waterproof outer housing and a plurality of waterproof electronics modules (WEMs) disposed inside of the outer housing. The WEMs include a battery pack. The power supply also includes a first waterproof fan affixed in a first opening of the outer housing and configured to draw air from outside to inside of the outer housing, and a second waterproof fan affixed in a second opening of the outer housing and configured to draw air from inside to outside. Other embodiments include a WEM configured for use inside of a non-waterproof power supply. The WEM includes a waterproof shell comprising first and second pieces of a material that is waterproof and heat-conductive and a waterproof seal or gasket disposed between the first and second pieces. The WEM also comprises one or more electronic components or an electronic assembly, encased within the shell.

### TECHNICAL FIELD

The present invention relates generally to devices that are capable of supplying AC and/or DC power to other devices (“power supplies”), and more specifically to power supplies that can operate safely in environments with significant moisture.

### BACKGROUND

Although AC power is widely available from the electrical grid in developed and developing countries, there remains many scenarios where AC power is needed but not available. Some of these scenarios involve building or construction operations on sites before connection to the electrical grid. Other of these scenarios involve recreation, such as in remote outdoor locations away from the electrical grid.

A widely used, conventional solution for these scenarios is a portable generator, which generally consists of an AC generator driven by an internal combustion engine that runs on gasoline or diesel fuel. Such portable generators are often used on construction sites, in remote recreation areas, at outdoor events, in recreational vehicles, etc. In view of these common uses, many portable generators are built to operate in conditions typically found in these environments, including the presence of moisture such as rain and snow.

Nevertheless, portable generators have various drawbacks that make them less than ideal for these common uses. For example, the internal combustion engines are noisy. While this may not be a problem at a construction site, it can be an issue in recreational scenarios, to the extent that generators may be restricted or even prohibited in such environments. As another example, the internal combustion engines emit pollutants from consuming the fuel, which may also contribute to their use being restricted or even prohibited in recreational environments. Moreover, users have to be very careful with exposure to these pollutants, since some of them (e.g., carbon monoxide, CO) can be very hazardous or even deadly to humans.

As yet another example, portable generators are very heavy for the amount of AC power they output, mainly due to the weight of the internal combustion engine and the fuel. This weight makes generators difficult to move and transport, i.e., less “portable”.

Recently, electric vehicles (EVs) have greatly increased in popularity. EVs are powered by on-board battery packs rather than conventional internal combustion engines, with the size of the battery pack being related to the size, weight, and performance requirements of the EV itself. Many different types of EVs are currently being produced or planned for production, including cars, trucks, buses, motorcycles, scooters, bicycles, forklifts, and trains. In addition to these EVs that operate on hard surfaces (e.g., roads), other current or planned EVs include aircraft, surface ships (e.g., boats, personal watercraft), underwater vessels, and spacecraft.

The battery packs used in most EVs contain a large collection of rechargeable cells and are controlled by battery management systems (BMS). A battery pack with built-in BMS may also be referred to as a “smart battery pack” or “intelligent battery pack.” Among other tasks, a BMS protects the battery pack from operating outside its safe operating area, monitors its state, calculates and reports battery status information, and receives control information from a host platform (e.g., vehicle).

### SUMMARY

Even though battery packs have successfully replaced internal combustion engines in EVs, portable generators have a different set of requirements and challenges that make the use of battery packs more challenging. For example, EV battery packs are typically in waterproof enclosures such that they are protected from the environment in which the EV operates. Moreover, EV battery packs have the benefit of airflow caused by the EV's motion, which can serve to dissipate the heat generated by the battery pack such that the battery pack operates within an acceptable temperature range.

In contrast, portable generators are generally not waterproof and are typically stationary, making heat dissipation more challenging. Moreover, making a portable generator waterproof to protect the battery pack (and other related electronics) would create even greater heat dissipation challenges, since heat generated by the battery pack (and other related electronics) would be trapped inside the waterproof structure.

An object of embodiments of the present disclosure is to provide a power supply that uses a battery pack as an energy source but can operate in similar environments and for similar applications as conventional, internal combustion portable generators, without the drawbacks of such conventional units.

Some embodiments include a power supply that includes a non-waterproof outer housing and a plurality of waterproof electronics modules (WEMs) disposed inside of the outer housing. The WEMs include a battery pack. The power supply also includes a first waterproof fan affixed in a first opening of the outer housing and configured to draw air from outside to inside of the outer housing, and a second waterproof fan affixed in a second opening of the outer housing and configured to draw air from inside to outside.

In some embodiments, the power supply is an AC power supply and the plurality of WEMs include the following:
the battery pack, configured to output DC power at a first DC voltage,
a DC/DC converter configured to accept DC power at the first DC voltage and to output DC power at a second DC voltage, and
a DC/AC converter configured to accept DC power at the first DC voltage and to output AC power at one or more AC voltages.

In some of these embodiments, the power supply also includes a first waterproof cable assembly that couples the battery module to the DC/DC converter and a second waterproof cable assembly that couples the battery module to the DC/AC converter. In some of these embodiments, the plurality of WEMs also includes a user interface module affixed to an inner surface of the outer housing.

In some embodiments, each WEM in the power supply includes the following: a shell made from material that is waterproof and heat-conductive, and one or more electronic components or an electronic assembly, encased within the shell. In some of these embodiments, the WEM shell includes a plurality of outward protrusions of the material, arranged to improve conduction of heat from inside to outside of the waterproof electronics module.

In some of these embodiments, the WEM shell includes a plurality of inward protrusions of the material, arranged to improve conduction of heat from inside to outside of the waterproof electronics module. In some variants of these embodiments, the plurality of inward protrusions of the material are arranged to be in contact with one or more of the following that generate heat inside the waterproof electronics module: one or more electronic components, and one or more portions of an electronic assembly.

In some embodiments, the WEM shell includes first and second pieces of the material that is waterproof and heat conductive, and a waterproof seal or gasket disposed between the first and second pieces. Various configurations and/or variants of the first and second pieces of the shell are disclosed herein.

In some embodiments, each of the WEMs is compliant with IP67. In some embodiments, the bottom side of the outer housing includes a plurality of holes arranged to drain moisture from inside of the outer housing. In some embodiments, the power supply is portable.

Other embodiments include a WEM configured for use inside of a non-waterproof power supply. The WEM includes a waterproof shell comprising first and second pieces of a material that is waterproof and heat-conductive and a waterproof seal or gasket disposed between the first and second pieces. The WEM also comprises one or more electronic components or an electronic assembly, encased within the shell. Different configurations and/or variants of such WEMs are disclosed herein.

These and other embodiments described herein can provide various benefits and/or advantages. By making individual components waterproof rather than an entire power supply, embodiments can reduce the overall cost of the power supply. Moreover, by making the internal components waterproof, embodiments facilitate the use of fans to produce airflow for heat dissipation, thereby enabling the power supply to provide greater power output without malfunction. By making the internal components waterproof, embodiments also facilitate use of the power supply in applications where significant moisture is present, which is not possible with conventional power supplies that use battery packs for an energy source. At a high level, embodiments reduce pollution emissions by facilitating replacement of internal combustion engines with battery packs in portable power supply applications.

These and other objects, features, and advantages of embodiments disclosed herein will become apparent upon reading the following Detailed Description in view of the Drawings briefly described below.

### BRIEF DESCRIPTION OF THE DRAWINGS

FIG. 1 shows a block diagram of a conventional power supply 100 that uses a battery pack as a fuel source.

FIG. 2 shows a block diagram of a power supply according to some embodiments of the present disclosure.

FIG. 3 shows a block diagram of an exemplary power generation sub-system within a power supply, according to some embodiments of the present disclosure.

FIG. 4 shows an exemplary waterproof connection arrangement for the power generation sub-system shown in FIG. 3.

FIG. 5 shows an exemplary control arrangement within a power supply, according to some embodiments of the present disclosure.

FIG. 6 shows a block diagram of a power supply according to some embodiments of the present disclosure.

FIG. 7 illustrates an exemplary construction of a waterproof electronics module (WEM), according to some embodiments of the present disclosure.

FIG. 8 illustrates an example of how a WEM shell can be formed to facilitate drainage of moisture, according to some embodiments of the present disclosure.

FIG. 9 illustrates a cross-sectional view of a WEM according to other embodiments of the present disclosure.

FIG. 10 shows two three-dimensional views of a portable power supply according to some embodiments of the present disclosure

### DETAILED DESCRIPTION

Some of the embodiments contemplated herein will now be described more fully with reference to the accompanying drawings. Other embodiments, however, are contained within the scope of the subject matter disclosed herein, the disclosed subject matter should not be construed as limited to only the embodiments set forth herein; rather, these embodiments are provided as examples to convey the scope of the subject matter to those skilled in the art.

Generally, all terms used herein are to be interpreted according to their ordinary meaning in the relevant technical field, unless a different meaning is clearly given and/or is implied from the context in which it is used. All references to a/an/the element, apparatus, component, means, step, etc. are to be interpreted openly as referring to at least one instance of the element, apparatus, component, means, step, etc., unless explicitly stated otherwise. The operations of any methods and/or procedures disclosed herein do not have to be performed in the exact order disclosed, unless an operation is explicitly described as following or preceding another operation and/or where it is implicit that one operation must follow or precede another operation. Any feature of any of the embodiments disclosed herein can be applied to any other embodiment, wherever appropriate. Likewise, any advantage of any of the embodiments can apply to any other embodiments. Other objects, features, and advantages of the disclosed embodiments will become apparent from the following description.

As mentioned above, there are various reasons why it is desirable to replace internal combustion engines with battery packs for use in portable generator applications. These reasons include reduced noise, pollution, and weight. However, even though battery packs have successfully replaced internal combustion engines in EV applications, portable generators have a different set of requirements and challenges that make the use of battery packs more difficult in this application.

For example, EV battery packs are typically in waterproof enclosures that protect them from the environment in which the EV operates. Moreover, EV battery packs have the benefit of airflow caused by the EV's motion, which can serve to dissipate the heat generated by the battery pack such that the battery pack operates within an acceptable temperature range. In contrast, portable generators are generally not waterproof and are typically stationary, making heat dissipation more challenging.

As used herein, the terms “power supply” and “AC power supply” refer to an apparatus intended to perform similar functions as a portable generator, except using a battery pack rather than internal combustion engine as energy source.

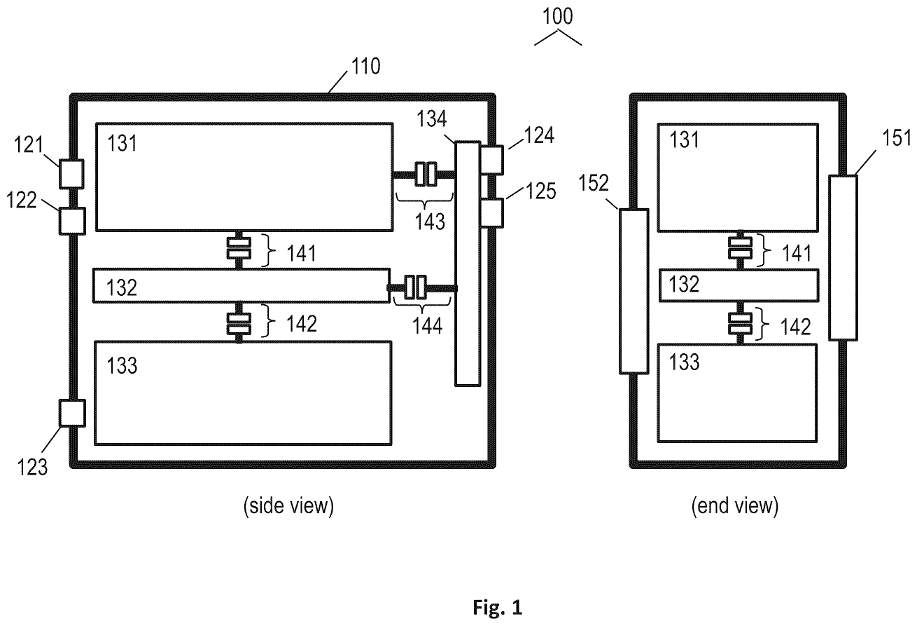

FIG. 1 shows a block diagram of a conventional power supply 100 that uses a battery pack as a fuel source. The power supply includes an outer housing 110 in which a plurality of user interface (UI) connectors 121-125 are mounted. These UI connectors can include one or more receptacles for AC plugs (e.g., 120 V, 240 V), one or more receptables for DC plugs (e.g., USB-A, USB-C, lighter receptacle), etc. Various electronics modules 131-134 are within the outer housing. For example, module 133 can be a battery pack, module 132 can be a DC/DC converter, module 131 can be a DC/AC converter, and module 134 can be a UI module.

Most battery packs (e.g., 133 in FIG. 1) contain a large collection of rechargeable cells and are controlled by a battery management system (BMS). A battery pack with built-in BMS may also be referred to as a “smart battery pack” or “intelligent battery pack.” Among other tasks, a BMS protects the battery pack from operating outside its safe operating area, monitors its state, calculates and reports battery status information, and receives control information from a host platform (e.g., EV, power supply, etc.). The BMS can also control the flow of current and/or energy from the battery pack to the host platform. In general, the BMS can control this flow based on conditions internal to the battery pack and/or commands from the host controller via a communications interface. The current/energy flow and the communications interface can be on the same or different connectors on the battery pack.

The battery pack outputs current at a first DC voltage, which the DC/DC converter receives and converts to a second DC voltage. The second DC voltage may be used to power the UI module, for example. The battery pack and the DC/DC converter are connected by a cable assembly 142.

Additionally, the DC/AC converter receives current at the second DC voltage from the DC/DC converter, and outputs current at one or more AC voltages (e.g., 120 V, 240 V). The AC voltages may be connected to one or more of the UI connectors (e.g., 121-122). The DC/AC converter and the DC/DC converter are connected by a cable assembly 141.

The UI module may include one or more displays and user input devices (e.g., keypad, buttons, switches, etc.) by which a user can monitor and control the operation of the power supply. Receptacles 121-124 are connected to the UI module, such that energy is provided to these receptacles via the UI module. The UI module is connected to the DC/AC converter and to the DC/DC inverter via respective cable assemblies 143, 144.

Fans 151-152 are disposed on opposing sides of the power supply. For example, fan 151 may operate to draw air from outside to inside of the power supply, while fan 152 may operate to draw air from inside to outside of the power supply. This airflow through the power supply can serve to remove and/or dissipate heat generate by the electronics modules 131-134 inside of the power supply during the conversion of the first DC voltage to the second DC voltage and the one or more AC voltages.

The heat dissipation facilitated by the fans is essential to operation of the power supply at its rated capacity (e.g., in W or A). For example, temperatures within the power supply can reach 100 C during normal operation, even with the fans running. If the fans were not present or not operational, the power supply would need to be operated at a lower capacity to reduce the amount of heat generated during the voltage conversion by the internal electronics modules. This is undesirable for an end user who may be relying on the rated capacity of the power supply.

Thus, the need to dissipate heat by airflow from/to outside is a primary reason why conventional power supplies such as shown in FIG. 1 are not waterproof in any way. In other words, the outer housing 110 is not waterproof, the internal electronics modules 131-134 are not waterproof, and the cable assemblies 141-144 are not waterproof. As such, conventional power supplies such as shown in FIG. 1 are not operable in environments that include significant moisture such as rain, snow, etc.

However, this is undesirable because many of the applications for which power supplies could replace internal combustion portable generators are found in these types of environments. For example, such power supplies would have significant utility in building or construction operations on sites before connection to the electrical grid. Such power supplies would also have significant utility in recreation applications, such as in remote outdoor locations away from the electrical grid. In these applications, the power supply would be subjected to rain, snow, and other moisture.

One straightforward solution to these needs is to modify the exemplary non-waterproof power supply in FIG. 1 to be completely waterproof. As used herein, the term “waterproof” can mean the power supply complies with a recognized industry standard, such as an ingress protection (IP) code defined by the International Electrotechnical Commission (IEC) under international standard IEC 60529. Compliance with an IP code indicates how well an apparatus is protected by its mechanical casings and/or electrical enclosures against intrusion, dust, accidental contact, and water. For example, an apparatus enclosure rated IP67 is “dust-tight” and “protected against the effects of temporary immersion in water”. More specifically, for an IP67-compliant enclosure, “ingress of water in harmful quantity shall not be possible when the enclosure is immersed in water under defined conditions of pressure and time”, specifically “up to 1 meter (3 ft 3 in) of submersion” for 30 minutes. In contrast, an apparatus rated IP47 has the same submersion tolerance but is less dust resistant. In the present disclosure, the term “waterproof” will be used to mean compliant with at least IP-x7 submersion tolerance requirements, where “x”=4, 6, etc.

For example, the outer housing 110 can be made waterproof. Also, the receptacles 121-125 and their respective attachments to the outer housing can also be made waterproof. One way to make the power supply waterproof is removal of the fans 151-152 and fully enclosing their respective openings in the outer housing. If the fans remain, moisture can enter through the fans in a similar way as air.

While removing the fans eliminates water ingress, it also eliminates the airflow needed for heat dissipation. Without airflow, internal temperatures may rise significantly during operation, causing malfunction of the power supply. Alternately, without airflow, the power supply would need to be operated at a lower output power to reduce the amount of heat generated, which is undesirable for an end user who may be relying on the rated output power of the power supply.

Embodiments of the present disclosure can address these and other issues, problems, and/or difficulties by power supplies that have all the benefits of being waterproof but none of the drawbacks. More specifically, according to various embodiments, the power supply can include a non-waterproof outer housing, a plurality of waterproof electronics modules disposed inside of the outer housing, and a plurality of waterproof fans affixed in respective openings in the outer housing. At least one of the waterproof fans can be configured to draw air from outside to inside of the outer housing, and at least one of the waterproof fans can be configured to draw air from inside to outside of the outer housing. In this manner, the plurality of fans provide airflow through the interior of the power supply, which dissipates heat generated by the waterproof electronics modules during normal operation.

Embodiments can provide various benefits and/or advantages. By making internal components (e.g., fans, electronics modules, cable assemblies) waterproof rather than the outer housing, embodiments can reduce the overall cost of the power supply. Moreover, by making the internal components (e.g., electronics modules, cable assemblies) waterproof, embodiments facilitate the use of the fans to produce airflow for heat dissipation, thereby enabling the power supply to provide greater output power without malfunction. Additionally, by making the internal components waterproof, embodiments facilitate use of the power supply in applications where significant moisture is present, which is not possible with conventional power supplies that use battery packs for an energy source.

Thus, even though water may freely enter the outer housing (e.g., through fans or other openings), the ingress of water is not harmful to the power supply so long as the water ingress remains unharmful to the internal components. Whether the entire power supply is classified as “waterproof” or “water-resistant”, or given a particular IP rating, may depend on testing of the entire power supply in conditions specified in IEC 60529.

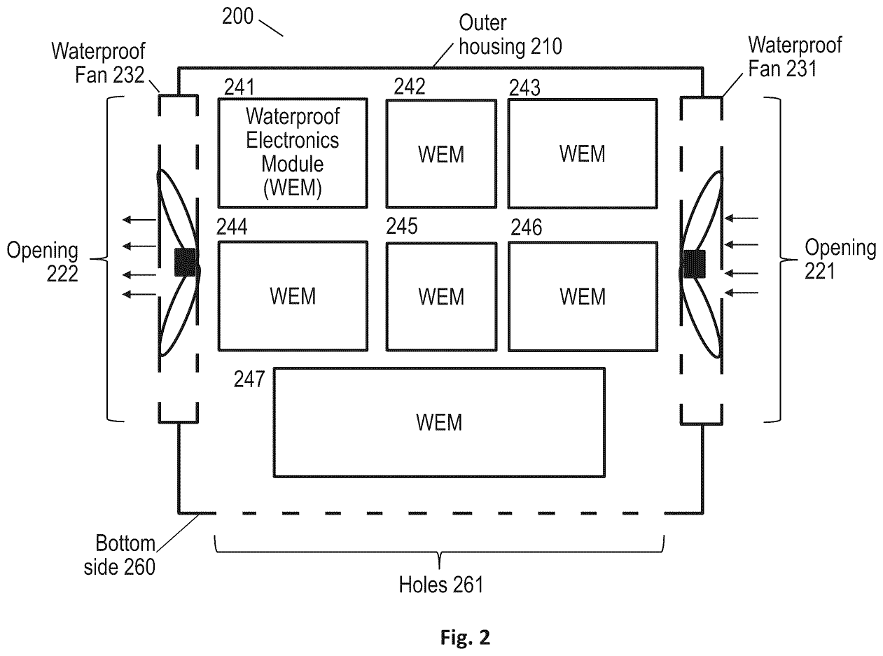

FIG. 2 shows a block diagram of a power supply (200) according to some embodiments of the present disclosure. Note that the view shown in FIG. 2 generally corresponds to a cross section of the power supply when it is in an upright orientation.

The power supply includes a non-waterproof outer housing (210), which has openings (221-222) on opposing sides. Waterproof fans are affixed within the respective openings. For example, a first waterproof fan (231) affixed in a first opening (231) can be configured to draw air from outside to inside of the outer housing during normal operation. Additionally, a second waterproof fan (232) affixed in a second opening (232) on an opposing side can be configured to draw air from inside to outside of the outer housing during normal operation. In this manner, the airflow created by the fans can dissipate heat generated by operation of various waterproof electronics modules (WEM) disposed within the outer housing.

Although the fans are waterproof, outside moisture can enter the outer housing through the openings, in a similar manner as the airflow. Water entering the outer housing will tend to collect on the bottom side (260) of the outer housing due to the effect of gravity. Accordingly, the bottom side includes a plurality of holes (261) or perforations, which will operate to drain any water collected on the bottom side.

A plurality of WEMs (241-247) are disposed within the outer housing. The WEMs may be mounted, affixed, attached, etc. to the outer housing and/or to a frame within the outer housing (not shown). The electronic functionality of these WEMs can be similar to one or more of the electronics modules shown in FIG. 1. For example, the WEMs can include a battery pack (e.g., with BMS), a DC/DC converter, a DC/AC converter, a UI module, etc. However, the WEMs are constructed to be waterproof against the moisture entering the power supply through the fan openings or through other openings that may be present in the outer housing. Some specific examples of waterproof construction of the WEMs are discussed below.

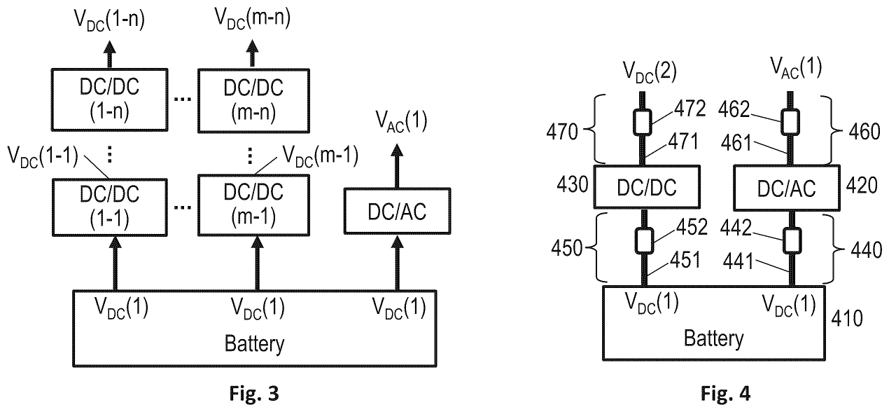

FIG. 3 shows a block diagram of an exemplary power generation sub-system within a power supply, according to some embodiments of the present disclosure. For example, the sub-system shown in FIG. 3 can be used in the power supply shown in FIG. 2. In this arrangement, a battery generates a first DC voltage, V_{DC}(1), which is provided to m≥1 DC/DC converters (i.e., 1-1 . . . m-1) and to a DC/AC converter. The DC/DC converters (1-1) . . . (m-1) generate respective output voltages V_{DC}(1-1) . . . . V_{DC}(m-1) based on V_{DC}(1) . . . . The respective output voltages V_{DC}(1-1) . . . . V_{DC}(m-1) may be input to respective DC/DC converters (1-2) . . . (m-2), which generate respective DC output voltages that can be used as inputs to further DC/DC converters. This is illustrated in FIG. 3 by respective DC/DC converter chains 1 . . . m with respective final outputs V_{DC}(1-n) . . . . V_{DC}(m-n). Note that any of the intermediate or final DC voltages generated by the respective DC/DC converter chains 1 . . . m may be output to a user. Additionally, the DC/AC converter generates a first AC voltage, V_{AC}(1), based on V_{DC}(1) . . .

FIG. 4 shows an exemplary waterproof connection arrangement for the power generation sub-system shown in FIG. 3. A first waterproof cable assembly (440) carries current at V_{DC}(1) from the battery (410) to the DC/AC converter (420). The first waterproof cable assembly includes mating waterproof connectors (442) attached to respective waterproof cables (441). In other words, each of battery (410) and DC/AC converter (420) has an attached waterproof cable with a connector, with the two connectors being configured to mate in a way that maintains a waterproof connection between battery (410) and DC/AC converter (420).

Similarly, a first waterproof cable assembly (450) carries current at Vpc (1) from the battery (410) to DC/DC converter (430). The second waterproof cable assembly includes mating waterproof connectors (452) attached to respective waterproof cables (451). In other words, each of battery (410) and DC/DC converter (430) has an attached waterproof cable with a connector, with the two connectors being configured to mate in a way that maintains a waterproof connection between battery (410) and DC/DC converter (430).

FIG. 4 also shows a third waterproof cable assembly (460) that carries current at V_{AC} (1) from the DC/AC converter (420) to a destination, such as an AC receptacle that protrudes through the outer housing. The third waterproof cable assembly includes mating waterproof connectors (462) attached to respective waterproof cables (461). FIG. 4 also shows a fourth waterproof cable assembly (470) that carries current at V_{DC}(2) from the DC/DC converter (430) to a destination, such as a DC receptacle that protrudes through the outer housing. The fourth waterproof cable assembly includes mating waterproof connectors (472) attached to respective waterproof cables (471). The third and fourth waterproof cable assemblies can be configured in a similar way as the first and second waterproof cable assemblies discussed above.

Note that the DC/DC converter (430) in FIG. 4 may be representative of multiple DC/DC converters, such as illustrated in FIG. 3. For example, in some embodiments, there may be respective waterproof cable assemblies (450a), (450b), etc. that connect the battery (410) to respective DC/DC converters (430a), (430b), etc. Likewise, there may be respective waterproof cable assemblies (470a), (470b), etc. that connect the outputs of respective DC/DC converters (430a), (430b), etc. to their respective destinations. For example, the respective DC/DC converters (430a), (430b), etc. may generate respective output voltages V_{DC}(2a), V_{DC}(2b), etc.

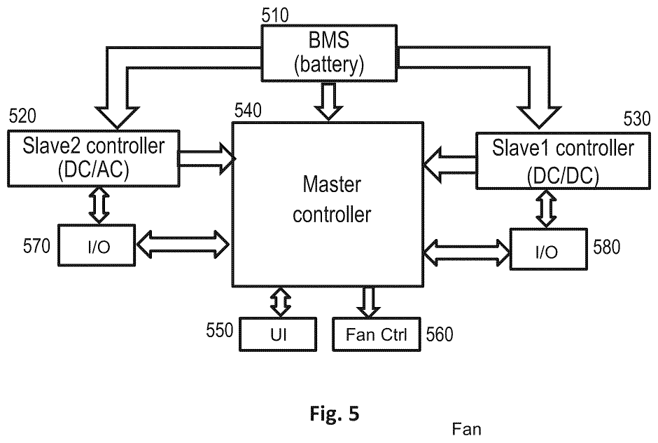

FIG. 5 shows an exemplary control arrangement within a power supply, according to some embodiments of the present disclosure. For example, the control arrangement shown in FIG. 5 can be used in the power supply shown in FIG. 2 and with the arrangement shown in FIG. 4.

The control arrangement in FIG. 5 includes a master controller (510), which can be included in a WEM of the power supply. The master controller communicates with a first slave controller (520) that is included in a DC/DC converter WEM, with a second slave controller (530) that is included in a DC/AC converter WEM, and with a BMS (510) that is included in a battery WEM. The BMS may also communicate with the first and second slave controllers.

The master controller may also communicate with a first I/O controller (570) associated with the first slave controller, and with a second I/O controller (580) associated with the second slave controller. The first and second I/O controllers may be included in the same WEMs as their associated slave controllers, or in separate WEMs. The I/O controllers may be responsible for controlling the outputs of their associated power converters to the user.

The master controller can also communicate with a UI controller (550), which may be included in a UI WEM. The UI WEM may include one or more displays and user input devices (e.g., keypad, buttons, switches, etc.) by which a user can monitor and control the operation of the power supply. For example, the UI controller may monitor the user input devices for actuation by a user, and report such actuation to the master controller. The UI controller may also cause information (e.g., numbers, characters, messages, etc.) to be rendered on the display(s), e.g., based on information received from the master controller and/or the user input devices.

The master controller can also communicate with a fan controller (560), which may be included in a fan controller (FC) WEM. The FC WEM may be connected to multiple waterproof fans in the power supply, e.g., via waterproof cable assemblies. The fan controller may control the on/off states and the rotational speeds of the respective fans, e.g., based on inputs received from the master controller.

The arrows in FIG. 5 denote control and/or status information communicated between the respective controllers, modules, etc. This control and/or status information may be communicated over respective waterproof cable assemblies, in a similar manner as the power flow illustrated in FIG. 4. For example, the control and/or status information between the BMS (510) and the second slave controller (520) may be carried over the same waterproof cable assembly as V_{DC}(1) power (e.g., assembly 440 shown in FIG. 4). Alternately, the control and/or status information between the BMS (510) and the second slave controller (520) may be carried over a second waterproof cable assembly that is separate from the waterproof cable assembly that carries V_{DC}(1) power between the battery pack and the DC/AC converter. Similar arrangements are possible for power and control/status between the battery pack and the DC/DC converter.

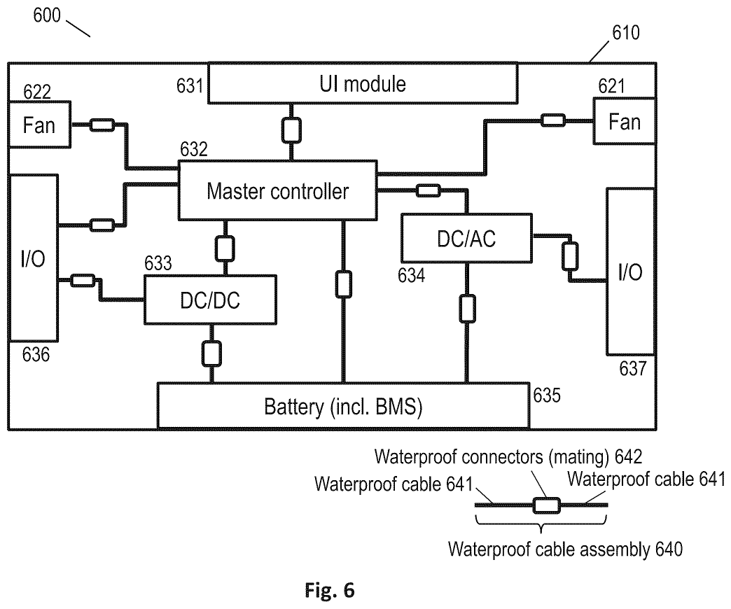

FIG. 6 shows a block diagram of a power supply (600) according to some embodiments of the present disclosure. The power supply includes an outer housing (610), which is non-waterproof. The power supply also includes two waterproof fans (621, 622), which may be affixed in respective openings of the outer housing (e.g., on opposing sides). For example, a first waterproof fan (621) can be configured to draw air from outside to inside of the outer housing during normal operation while a second waterproof fan (622) on an opposing side can be configured to draw air from inside to outside of the outer housing during normal operation. In this manner, the airflow created by the fans can dissipate heat generated by operation of various WEMs disposed within the outer housing.

In the embodiments illustrated in FIG. 6, the following WEMs are disposed inside of the outer housing of the power supply:
a UI module (631), e.g., with functionality similar to UI modules described above;
a master controller (632), e.g., with functionality described above in relation to FIG. 5;
a DC/DC converter (633), with functionality similar to DC/DC converters described above;
a DC/AC converter (634), with functionality similar to DC/AC converters described above;
a battery pack (635) including a BMS, with functionality similar to battery packs described above;
a first I/O module (636), which may be configured to control DC/DC converter output V_{DC}(2) to the user; and
a second I/O module (637), which may be configured to control DC/AC converter output V_{AC} (1) to the user.

FIG. 6 also shows various waterproof cable assemblies (640) that connect the respective modules. As shown at the bottom of the figure, each waterproof cable assembly (640) between two WEMs includes mating waterproof connectors (642) attached to respective waterproof cables (641). In other words, each of the two WEMs (e.g., battery and DC/AC) has an attached waterproof cable with a connector, with the two connectors being configured to mate in a way that maintains a waterproof connection between the two WEMs. In cases where control/status and power must be carried between two modules, this can be done with a single waterproof cable assembly or with two waterproof cable assemblies-one carrying power and another carrying control/status.

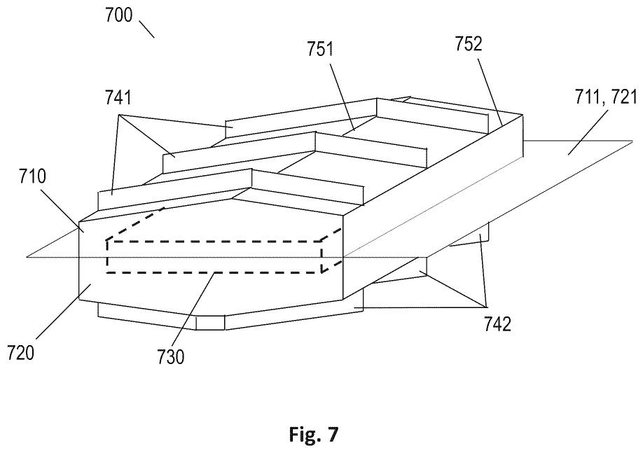

FIG. 7 illustrates an exemplary construction of a WEM (700), according to some embodiments of the present disclosure. At a high level, the WEM includes a shell made (e.g., fabricated, milled, cast, etc.) from a material that is waterproof and heat conductive. Some examples of suitable materials include aluminum, aluminum alloy, magnesium, magnesium alloy, etc. The WEM shown in FIG. 7 includes first and second pieces (710, 720) of the material that is waterproof and heat conductive. In the orientation shown in FIG. 7, the first piece (710) can be considered an upper piece and the second piece (720) can be considered a lower piece.

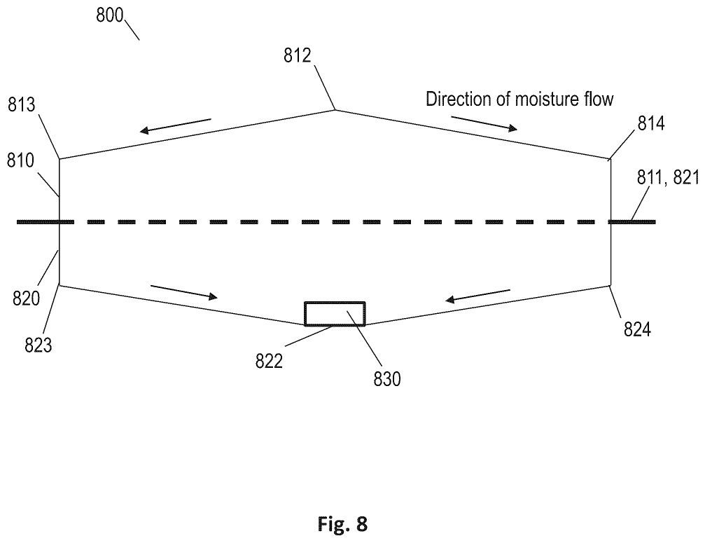

Although not shown in FIG. 7, the WEM also includes a waterproof seal or gasket disposed between the first and second pieces. This aspect will be described below in relation to FIG. 8. The waterproof seal or gasket may be disposed between a flange (711) of the first piece of material and a flange (721) of the second piece of material. These flanges may appear in FIG. 7 as a single flange due to the perspective shown.

Encased within the shell are one or more electronic components or an electronic assembly. As a specific example, a battery pack WEM can include within its shell an electronic assembly comprising a plurality of rechargeable cells and a BMS. As another specific example, a DC/DC converter WEM can include within its shell an electronic assembly (e.g., circuit board) of components that forms a switching circuit for conversion of an input DC voltage to a different output DC voltage.

The shell of the WEM also includes a plurality of outward protrusions of the material, arranged to improve conduction of heat from inside to outside of the WEM. For example, the protrusions can be configured to improve heat conduction by increasing the shell's surface area from which heat can radiate into the surrounding environment. In FIG. 7, the first piece (710) includes a first plurality of protrusions (741) while the second piece includes a second plurality of protrusions (742). In this example, each of the protrusions is approximately linear in form, possibly giving the appearance of a “fin”.

Also, each of the protrusions runs between two edges of its associated piece of material with an orientation that is approximately perpendicular to the two edges. For example, the first plurality of protrusions (741) are approximately perpendicular to edge (752) of the first piece (710). In some embodiments, each plurality of protrusions may be equally spaced along the edges of the associated piece of material. For example, the first plurality of protrusions (741) may be equally spaced along edge (752) of the first piece (710).

In FIG. 7, the first (or upper) piece of the shell is formed such that, when the power supply is in an upright orientation, the first piece of the shell slopes downward from center to edges, e.g., from center line (751) to edge (752). In other words, an outer upper surface of the shell slopes downward from center to edges, such that moisture will drain off the outer upper surface. Note that “center” does not necessarily refer to an exact centerline between the two edges, but can include some line (or area) that is intermediate between the two edges and facilitates the drainage of moisture towards both edges.

FIG. 8 illustrates another example of how the shell of a WEM can be formed to facilitate drainage of moisture. The WEM shown in FIG. 8 includes first and second pieces (810, 820) of the material that is waterproof and heat conductive. In the orientation shown in FIG. 8, the first piece (810) can be considered an upper piece and the second piece (820) can be considered a lower piece. Although not shown in FIG. 8, the WEM also includes a waterproof seal or gasket disposed between the first and second pieces. The waterproof seal or gasket may be disposed between a flange (811) of the first piece of material and a flange (821) of the second piece of material. These flanges may appear in FIG. 8 as a single flange due to the perspective shown.

In the arrangement shown in FIG. 8, the first (or upper) piece of the shell is formed such that, when the power supply is in an upright orientation, the first piece of the shell slopes downward from center line (812) to edges (813, 814). In other words, an outer upper surface of the shell slopes downward from center to edges, such that moisture will drain off the outer upper surface. Arrows indicate the direction of moisture flow in FIG. 8.

In the arrangement shown in FIG. 8, the second (or lower) piece of the shell is formed such that, when the power supply is in an upright orientation, the second piece of the shell slopes downward from edges (823, 824) to center area (822). In other words, the inner bottom surface of the shell slopes downward from edges to a lowest point or area, such that moisture inside the shell collects at the lowest point or area. In the example shown in FIG. 8, the lowest point or area is the approximate center of the inner bottom surface.

The WEM shown in FIG. 8 also includes a water detection device (830) disposed at the lowest point or area (822) of the inner bottom surface of the shell. For example, the device (830) can be connected to, or be part of, an electronic assembly within the WEM shell. When some amount of moisture collects at the lowest point or area inside the bottom piece of the shell, the device (830) may send an alert or other notification of this event to the electronic assembly, which may process the alert and/or forward it as status information to a master controller WEM. Although the shell is intended to be waterproof, the device (830) protects against unintended moisture incursions such as due to failure of the waterproof seal or gasket between the upper and lower pieces of the shell. An example water detection device that may be suitable for this purpose is a capacitive-type sensor with two electrodes, where the presence of water between the two electrodes will complete a circuit thus triggering a signal from the sensor.

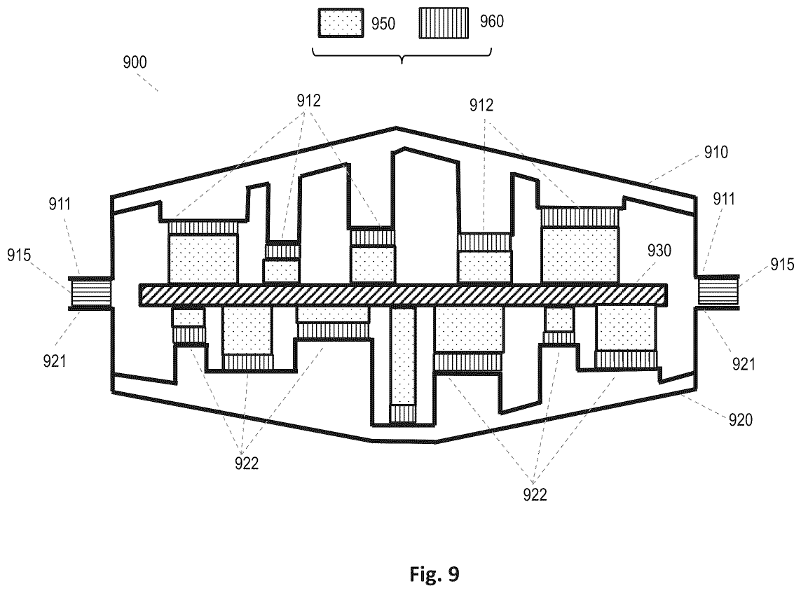

FIG. 9 illustrates a cross-sectional view of a WEM (900) according to other embodiments of the present disclosure. Similar to the WEMs shown in FIGS. 7-8, the WEM shell in FIG. 9 includes first and second pieces (910, 920) of a material that is waterproof and heat conductive. Some examples of suitable materials include aluminum, aluminum alloys, magnesium, magnesium alloys, etc. In the orientation shown in FIG. 9, the first piece (910) can be considered an upper piece and the second piece (920) can be considered a lower piece.

The WEM in FIG. 9 also includes a waterproof seal or gasket (915) disposed between the first and second pieces. The waterproof seal or gasket may be disposed between a flange (911) of the first piece of material and a flange (921) of the second piece of material. Some example materials that may be suitable for the waterproof seal or gasket include natural rubber, synthetic rubber, silicone, foam, etc. As a more specific example, an O-ring type of waterproof gasket with a circular cross section can be used.

Within the WEM is an electronic assembly (930) that includes a plurality of electronic components (950) mounted to a circuit board or other carrier. Also, the WEM shell includes a plurality of inward protrusions of the material, arranged to improve conduction of heat from inside to outside of the waterproof electronics module. For example, the inward protrusions can be configured to improve heat conduction by increasing the shell's surface area to absorb heat generated inside the shell by the electronic assembly (930).

In particular, the first (or upper) piece (910) of shell material includes a first plurality of inward protrusions (912) and the second (or lower) piece (920) of shell material includes a second plurality of inward protrusions (922). Each of the inward protrusions is arranged to be in contact with an electronic component or a portion of the electronic assembly (930). In this manner, heat generated by the electronic component or portion can be absorbed more directly by the heat-conductive shell, thereby facilitating dissipation of the heat into the environment outside of the shell (i.e., inside the power supply). In some embodiments, each of the inward protrusions can be arranged to be in contact via a heat-conductive intermediate material (960). Some example heat-conductive materials suitable for this purpose include epoxy resin, silicone glue or pad, polyurethane resin, etc.

Additionally, the arrangement of the inward protrusions as shown in FIG. 9 increases the surface area on the inside of the shell, which also facilitates absorption of the heat generated by the electronic assembly within the shell.

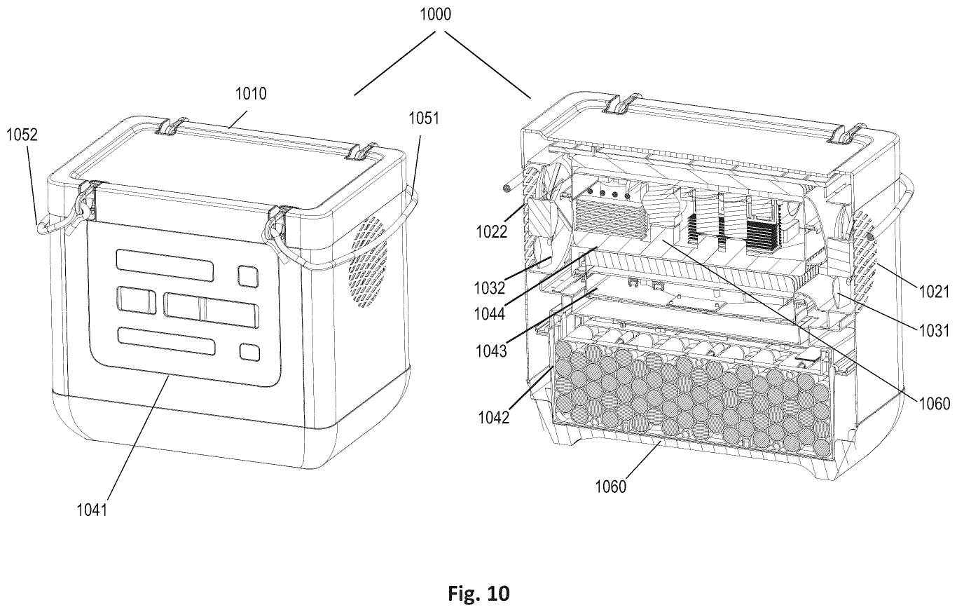

FIG. 10 shows two three-dimensional views of a portable power supply (1000) according to some embodiments of the present disclosure. The power supply includes an outer housing (1010) that is non-waterproof. Attached to the outer housing are two handles (1051, 1052) by which the power supply can be carried or moved. In other embodiments, the two handles can be replaced by, or supplemented with, two wheels attached to the bottom of the power supply and a single handle by which the power supply can be pulled to roll on the two wheels.

As shown in the left view, the power supply can include a UI module (1041), which can have similar functionality as UI modules discussed above in relation to other embodiments. The UI module can be waterproof and can connect to other WEMs in the power supply via one or more waterproof cable assemblies (not shown).

As shown in the right view, the power supply can include two waterproof fans (1031, 1032) affixed in respective openings (1021, 1022) on opposing sides of the outer housing. For example, one of the fans (e.g., 1031) can be configured to draw air from outside to inside of the outer housing while the other fan (e.g., 1032) can be configured to draw air from inside to outside of the outer housing. This airflow facilitates dissipation of the heat generated by WEMs inside of the outer housing.

These WEMs can include a battery pack (1042), a DC/DC converter (1043), and a DC/AC inverter (1044). Each of these WEMs can be constructed of two-piece shell of material that is waterproof and heat conductive. A waterproof seal or gasket can be disposed between the two pieces, e.g., between respective flanges around the outer edges of the two pieces such as shown in FIG. 9. Also, note that the shell of DC/AC converter WEM (1044) includes multiple inward protrusions (e.g., 1060) that are arranged to be in contact with electronic components that generate heat inside this WEM.

The foregoing merely illustrates the principles of the disclosure. Various modifications and alterations to the described embodiments will be apparent to those skilled in the art in view of the teachings herein. It will thus be appreciated that those skilled in the art will be able to devise numerous systems, arrangements, and procedures that, although not explicitly shown or described herein, embody the principles of the disclosure and can be thus within the spirit and scope of the disclosure. Various exemplary embodiments can be used together with one another, as well as interchangeably therewith, as should be understood by those having ordinary skill in the art.

Any appropriate steps, methods, features, functions, or benefits disclosed herein may be performed through one or more functional units or modules of one or more virtual apparatuses. Each virtual apparatus may comprise a number of these functional units. These functional units may be implemented via processing circuitry, which may include one or more microprocessor or microcontrollers, as well as other digital hardware, which may include Digital Signal Processor (DSPs), special-purpose digital logic, and the like. The processing circuitry may be configured to execute program code stored in memory, which may include one or several types of memory such as Read Only Memory (ROM), Random Access Memory (RAM), cache memory, flash memory devices, optical storage devices, etc. Program code stored in memory includes program instructions for executing one or more telecommunications and/or data communications protocols as well as instructions for carrying out one or more of the techniques described herein. In some implementations, the processing circuitry may be used to cause the respective functional unit to perform corresponding functions according to one or more embodiments of the present disclosure.

As described herein, device and/or apparatus can be represented by a semiconductor chip, a chipset, or a (hardware) module comprising such chip or chipset; this, however, does not exclude the possibility that a functionality of a device or apparatus, instead of being hardware implemented, be implemented as a software module such as a computer program or a computer program product comprising executable software code portions for execution or being run on a processor. Furthermore, functionality of a device or apparatus can be implemented by any combination of hardware and software. A device or apparatus can also be regarded as an assembly of multiple devices and/or apparatuses, whether functionally in cooperation with or independently of each other. Moreover, devices and apparatuses can be implemented in a distributed fashion throughout a system, so long as the functionality of the device or apparatus is preserved. Such and similar principles are considered as known to a skilled person.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In addition, certain terms used in the present disclosure, including the specification and drawings, can be used synonymously in certain instances (e.g., “data” and “information”). It should be understood, that although these terms (and/or other terms that can be synonymous to one another) can be used synonymously herein, there can be instances when such words can be intended to not be used synonymously.

1. A power supply comprising:
a non-waterproof outer housing;
a plurality of waterproof electronics modules (WEMs) disposed inside of the outer housing, wherein one of the WEMs is a battery pack;
a first waterproof fan affixed in a first opening of the outer housing and configured to draw air from outside to inside of the outer housing; and
a second waterproof fan affixed in a second opening of the outer housing and configured to draw air from inside to outside of the outer housing.

2. The power supply of claim 1, the power supply is an AC power supply and the plurality of WEMs include:
the battery pack, configured to output DC power at a first DC voltage,
one or more DC/DC converters configured to accept DC power at the first DC voltage and to output DC power at respective one or more second DC voltages, and
a DC/AC converter configured to accept DC power at the first DC voltage and to output AC power at one or more AC voltages.

3. The power supply of claim 2, further comprising:
a first waterproof cable assembly that couples the battery module to a first one of the DC/DC converters; and
a second waterproof cable assembly that couples the battery module to the DC/AC converter.

4. The power supply of claim 2, wherein the plurality of WEMs also includes a user interface module affixed to an inner surface of the outer housing.

5. The power supply of claim 4, further comprising one or more of the following:
a third waterproof cable assembly that couples a first one of the DC/DC converters to the user interface module; and
a fourth waterproof cable assembly that couples the DC/AC converter to the user interface module.

6. The power supply of claim 4, wherein the user interface module is coupled to one or more AC power connectors disposed in respective one or more openings of the outer housing.

7. The power supply of claim 1, wherein the first and second openings are on opposing sides of the outer housing.

8. The power supply of claim 1, wherein each WEM includes the following:
a shell made from material that is waterproof and heat-conductive; and
one or more electronic components or an electronic assembly, encased within the shell.

9. The power supply of claim 8, wherein for at least one of the WEMs, the shell includes a plurality of outward protrusions of the material, arranged to improve conduction of heat from inside to outside of the waterproof electronics module.

10. The power supply of claim 8, wherein for at least one of the WEMs, the shell includes a plurality of inward protrusions of the material, arranged to improve conduction of heat from inside to outside of the waterproof electronics module.

11. The power supply of claim 10, wherein for at least one of the WEMs, the plurality of inward protrusions of the material are arranged to be in contact with one or more of the following that generate heat inside the waterproof electronics module: one or more electronic components, and one or more portions of an electronic assembly.

12. The power supply of claim 11, wherein the plurality of inward protrusions of the material are arranged to be in contact via an intermediate material that is heat conductive.

13. The power supply of claim 8, wherein each shell includes:
first and second pieces of the material that is waterproof and heat conductive; and
a waterproof seal or gasket disposed between the first and second pieces.

14. The power supply of claim 8, wherein for at least one of the WEMs, the shell is formed such that, when the power supply is in an upright orientation, an outer upper surface of the shell slopes downward from center to edges, such that moisture will drain off the outer upper surface.

15. The power supply of claim 8, wherein for at least one of the WEMs, the shell is formed such that, when the power supply is in an upright orientation, an inner bottom surface of the shell slopes downward from edges to a lowest point or area, such that moisture inside the shell collects at the lowest point or area.

16. The method of claim 15, wherein the lowest point or area is an approximate center of the inner bottom surface.

17. The power supply of claim 15, where the at least one WEM includes a water detection device disposed at the lowest point or area of the inner bottom surface of the shell.

18. The power supply of claim 8, wherein the shell is fabricated from one of the following heat-conductive materials: aluminum, aluminum alloy, magnesium, and magnesium alloy.

19. The power supply of claim 1, wherein each of the WEMs is compliant with IP67.

20. The power supply of claim 1, wherein a bottom side of the outer housing includes a plurality of holes arranged to drain moisture from inside of the outer housing.

21. The power supply of claim 1, wherein the power supply is portable.

22. A waterproof electronics module (WEM) configured for use inside of a non-waterproof power supply, wherein the WEM comprises:
a waterproof shell comprising:
first and second pieces of a material that is waterproof and heat-conductive, and
a waterproof seal or gasket disposed between the first and second pieces; and
one or more electronic components or an electronic assembly, encased within the shell.

23. The WEM of claim 22, wherein the waterproof shell further comprises one or more of the following arranged to improve conduction of heat from inside to outside of the waterproof electronics module: a plurality of outward protrusions of the material, and a plurality of inward protrusions of the material.

24. The WEM of claim 23, wherein the plurality of inward protrusions of the material are arranged to be in contact with one or more of the following that generate heat inside the waterproof electronics module: one or more electronic components, and one or more portions of the electronic assembly.

25. The WEM of claim 22, wherein the waterproof shell is formed such that, when the power supply is in an upright orientation, one or more of the following applies:
an outer surface of the first piece slopes downward from center to edges, such that moisture will drain off the outer surface of the first piece; and
an inner surface of the second piece slopes downward from edges to a lowest point or area, such that moisture inside the waterproof shell collects at the lowest point or area.

26. The WEM of claim 22, wherein the WEM is one of the following:
a battery pack configured to output DC power at a first DC voltage,
a DC/DC converter configured to accept DC power at a first DC voltage and to output DC power at a second DC voltage,
a DC/AC converter configured to accept DC power at a first DC voltage and to output AC power at one or more AC voltages, or
a user interface module.
